(19) United States
(12) Patent Application Publication
(10) Pub. No.: US 2002/0024092 A1
(43) Pub. Date: Feb. 28, 2002

(54) Memory cell, memory cell arrangement and fabrication method

(76) Inventors: Herbert Palm, Hohenkirchen (DE); Josef Willer, Riemerling (DE)

Correspondence Address: LERNER AND GREENBERG, P.A., POST OFFICE BOX 2480, HOLLYWOOD, FL, 33022-2480, US

(21) Appl. No.: 09/900,654

(22) Filed: Jul. 6, 2001

(30) Foreign Application Priority Data
Aug. 11, 2000 (DE) 100 39 441.8

(51) Int. Cl. H01L 29/76; H01L 31/113; H01L 21/8238

(52) U.S. Cl. 257/330; 257/329; 438/212; 438/259; 438/270

(57) ABSTRACT

Each memory cell is a memory transistor which is provided on a top side of a semiconductor body with a gate electrode (2) which is arranged in a trench between a source region (3) and a drain region (4), which are formed in the semiconductor material. The gate electrode is separated from the semiconductor material by dielectric material. At least between the source region and the gate electrode and between the drain region and the gate electrode there is an oxide-nitride-oxide layer sequence (5, 6, 7), which is provided for the purpose of trapping charge carriers at source and drain.

The invention relates to the field of electrically writable and erasable non-volatile flash memories. It describes a non-volatile memory cell which is constructed in accordance with the SONOS principle (semiconductor-oxide-nitride-oxide-semiconductor) and can be used in a virtual-ground-NOR architecture.

Extremely small non-volatile memory cells are required for very large scale integration densities for multimedia applications. Ongoing development in semiconductor technology allows increasingly large storage capacities, which will very soon reach the gigabit range. However, while the minimum feature size, which is determined by lithography, continues to decrease, other parameters, such as for example the thickness of the tunnel oxide, can no longer be scaled accordingly. The associated reduction in the channel length in planar transistors with smaller features requires an increase in the channel doping, in order to avoid the occurrence of a punch-through between source and drain. This leads to an increase in the threshold voltage, which is usually compensated for by a reduction in the thickness of the gate oxide.

However, planar SOSNOS memory cells which can be programmed by channel-hot-electrons and can be erased using hot holes (cf. U.S. Pat. No. 5,768,192, U.S. Pat. No. 6,011,725, WO 99/60631) require a control dielectric with a thickness which is equivalent to a gate oxide. However, this thickness cannot be reduced as desired without the number of programming cycles which can be executed (the endurance of the memory cell) falling unacceptably. Therefore, a sufficiently great channel length to ensure that the dopant concentration in the channel does not have to be selected to be excessively high is required, since otherwise the threshold voltage rises too greatly.

The publication by J. Tanaka et al.:“A Sub-0.1-μm Grooved Gate MOSFET with High Immunity to Short-Channel Effects” in IEDM 93, pp. 537-540 (1993) describes a transistor on a p⁺substrate, in which the gate electrode is arranged in a trench between the n⁺-source region and the n⁺-drain region, so that in this way a curved channel region is formed in the substrate.

The publication by K. Nakagawa et al.:“A Flash EEPROM Cell with Self-Aligned Trench Transistor & Isolation Structure” in 2000 IEEE Symposium on VLSI Technology Digest of Technical Papers describes a transistor as a memory cell with a floating-gate electrode, which is arranged between the n⁺-source region and the n⁺-drain region, extending into a p-well of the substrate. Between the floating-gate electrode and the control-gate electrode there is a dielectric layer of an oxide-nitride-oxide layer sequence.

DE 195 45 903 A1 has described a read-only memory cell arrangement, in which planar MOS transistors are arranged in parallel cells. Adjacent cells run alternately at the base of longitudinal trenches and between adjacent longitudinal trenches. The bit lines run transversely and the word lines parallel to the longitudinal trenches.

DE 196 00 422 C1 has described an electrically programmable memory cell arrangement in which there is a multiplicity of individual memory cells which each comprise an MOS transistor with a gate dielectric with traps and which are arranged in parallel rows. Adjacent rows in each case run alternately at the base of longitudinal trenches and between adjacent longitudinal trenches and are isolated from one another.

DE 196 03 810 C1 has described a memory cell arrangement which comprises first memory cells with planar MOS transistors and second memory cells with vertical MOS transistors. The planar MOS transistors are in this case arranged at the base of and on the crown of parallel trenches which are in strip form. The vertical MOS transistors are arranged on the side walls of the trenches.

It is an object of the present invention to provide a memory cell for a memory cell arrangement which requires very little surface area and to provide an associated fabrication method. This object is achieved by the memory cell having the features of claim 1, by the arrangement of memory cells having the features of claim 15 and by the method having the features of claim 21. Configurations will emerge from the dependent claims.

The memory cell according to the invention has a memory transistor which is provided on the top side of a semiconductor body or of a semiconductor layer with a gate electrode arranged between a source region and a drain region which are formed in the semiconductor material. The gate electrode is separated from the semiconductor material by dielectric material. At least between the source region and the gate electrode and between the drain region and the gate electrode there is a layer sequence which comprises a memory layer, which is intended to trap charge carriers at source and drain, between boundary layers. The material of the boundary layers has a higher energy band gap than the material of the memory layer, so that the charge carriers which are trapped in the memory layer between the boundary layers remain located in that area.

A suitable material for the memory layer is preferably a nitride; an oxide is primarily suitable as surrounding material. In the case of a memory cell in the silicon material system, the memory layer is in this example silicon nitride with an energy band gap of approximately 5 eV, while the surrounding boundary layers are silicon oxide with an energy band gap of approximately 9 eV. The memory layer may be a different material with a smaller energy band gap than that of the boundary layers, the intention being that the difference between the energy band gaps should be as great as possible, for good electrical confinement of the charge carriers. Traps or trapping centers are preferably provided in the memory layer and form energy levels within the energy band gap of the memory layer which are to be occupied by charge carriers.

The lower boundary layer, which faces the semiconductor material, is to be so thick that direct tunneling of the charge carriers is avoided. When using SiO₂, the lower boundary layer is therefore preferably at least approximately 6 nm to 7 nm thick. The upper boundary layer, which faces the gate electrode, is preferably typically about twice as thick as the lower boundary layer, in order to avoid direct tunneling and Fowler-Nordheim tunneling out of the gate during the erasing operation.

The layer sequence comprising the memory layer and the boundary layers is preferably formed with a low oxide-equivalent thickness, which is intended to mean the thickness of a pure oxide layer as dielectric for forming the same capacitance. For this purpose, the materials of the layers are selected in such a way that a mean relative dielectric constant of the layer sequence is more than 4. This is preferably achieved by the fact that the material of the lower boundary layer which faces the semiconductor material is formed with a relative dielectric constant of at least 3.9, corresponding to that of SiO₂. It is even better if the relative dielectric constant is selected to be higher, at least approximately 7.8, since in this way improved gate control is achieved and more rapid programming is possible. This is because this reduces the electrically active thickness of the gate dielectric, and a thinner lower boundary layer allows higher programming rates and/or lower programming voltages.

In this context, it is necessary to take into account the fact that the barrier level between the semiconductor material and the memory layer must remain sufficiently high. This barrier level generally decreases as the relative dielectric constant the material of the lower boundary layer increases. In the case of SiO₂ on Si, the barrier level is approximately 3.1 eV; this is the distance of the Fermi level of the electrons in the silicon from the lower edge of the conduction band in the SiO₂ layer. This barrier level should not fall below 2 eV. Conversely, a low barrier level is advantageous, since the programming rate in this case increases drastically and opens up the possibility of reducing the source/drain voltage and therefore of reducing the risk of a punch-through in the channel. If demands allow, therefore, the material of the lower boundary level may advantageously also have a relative dielectric constant of at least 20.

Since the interface between silicon and silicon dioxide is well controlled, a lower boundary layer of SiO₂ is advantageous. By way of example, tantalum oxide, hafnium silicate, titanium oxide (TiO₂ in the case of a stoichiometric composition), titanate, tantalum oxide (Ta₂O₅ in the case of a stoichiometric composition), tantalate, zirconium oxide (ZrO₂ in the case of a stoichiometric composition), aluminum oxide (Al₂O₃ in the case of a stoichiometric composition) or intrinsically conductive (undoped) silicon can be used as material for the memory layer in combination with silicon oxide. Silicon nitride has a relative dielectric constant of about 7.9. The use of an alternative material with a higher dielectric constant (e.g.=15 . . . 18) allows the oxide-equivalent total thickness of the layer stack provided for the storage to be reduced and is therefore advantageous. On the other hand, silicon nitride can also be used to good effect as the lower boundary layer. In this case, silicon oxynitride may also be used instead of a pure silicon nitride; in this case, the oxygen and nitrogen levels may be varied continuously or in steps from the semiconductor material toward the memory layer.

The listed materials tantalum oxide, hafnium silicate, titanium oxide, zirconium oxide and aluminum oxide, but also tantalum oxide (Ta₂O₅ for a stoichiometric composition), titanate and tantalate are also suitable as materials for the boundary layers. The use of silicates in the boundary layers should be particularly emphasized. By way of example, hafnium silicate, in this case preferably without traps, may be used to good effect. In this way, it is also possible to achieve a continuously varying composition of the lower boundary layer, in which, in order to achieve a good interface with the silicon of the substrate or semiconductor body, SiO₂ is present at the bottom, and toward the top, i.e. toward the memory layer, this material is increasingly mixed with hafnium, so that if appropriate a stoichiometric composition of a hafnium silicate is reached. Toward the memory layer, the silicon content of the material may decrease, until ultimately only HfO₂ is present adjacent to the memory layer. The result is a barrier level between the semiconductor material and the memory layer which is reduced from 3.1 eV, when exclusively SiO₂ is used, to approximately 2 eV. A corresponding continuous variation of the composition of a lower boundary layer based on SiO₂ is also possible with other chemical elements instead of hafnium, preferably with metals, as additives, for example with titanium, zirconium or lanthanum. As well as silicates, Al₂O₃ and Ta₂O₅ are of particular interest for the upper boundary layer, a combination with titanate, titanium dioxide, tantalate or tantalum pentoxide being preferably suitable in the memory layer.

The layer sequence comprising a boundary layer, a memory layer and a further boundary layer may be applied to the entire surface of a top side of the semiconductor body, so that sections of the memory layer are also present on the regions of this surface which are horizontal with respect to this top side and on the bases of the trenches which are filled with the gate electrodes. Alternatively, the memory layer may be delimited as a result of the layer sequence comprising the memory layer in each case being present on the walls of a trench which is present in the semiconductor material and in which respective gate electrodes are arranged and being interrupted between these walls.

The memory cells according to the invention may be connected as a memory cell arrangement in a virtual-ground-NOR architecture, it being possible to achieve a channel length which can be selected freely within wide limits. This is achieved by forming trenches in a semiconductor body. The trenches may be etched, for example, in an n⁺region which has already been produced, so that the channel regions at the base of these trenches have a curvature directed toward the semiconductor body or are guided more deeply with respect to the source and drain regions. The channel regions simultaneously form the bit lines. The advantages of this arrangement lie in particular in the possibility of in this way taking up the smallest possible area at the level of the top side of the semiconductor body (crosspoint cell), the area contracting with the fineness of pattern which can be achieved by lithography (relates to the shrinkability criterion). Moreover, the channel length of the memory transistors can be optimized by means of the depth of the trenches and the shape of the trench bases. Low threshold voltages of less than 1 V and higher source-drain voltages are possible than with planar transistors of the same scale (design rule).

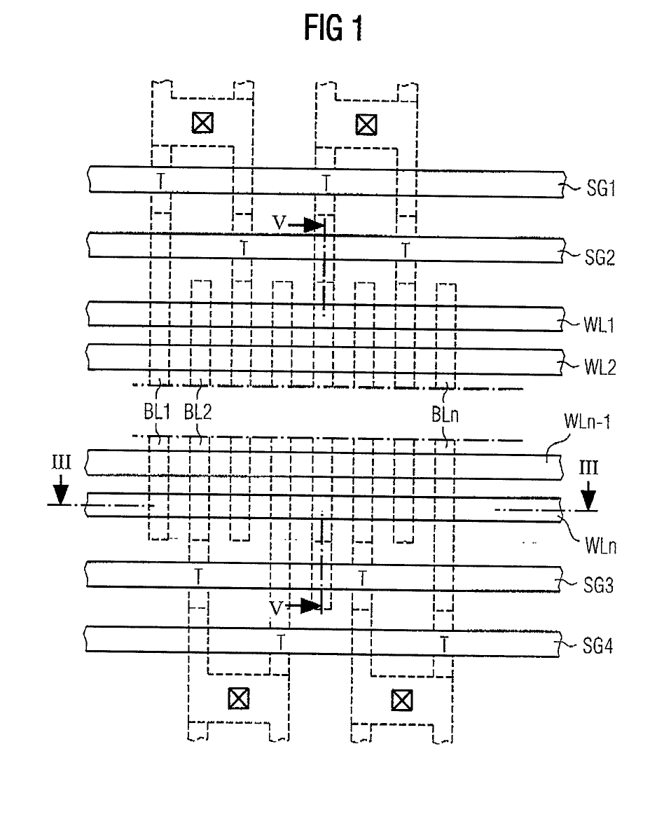

There now follows a more detailed description of examples of the memory cells according to the invention and of the fabrication method, with reference to FIGS. 1 to 13.

FIG. 1 shows a plan view of a memory cell arrangement.

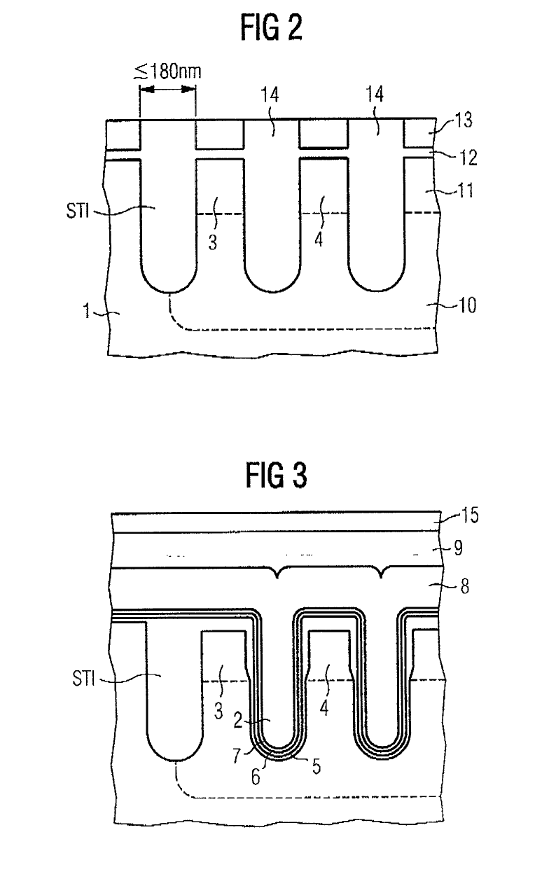

FIGS. 2 and 3 show the cross section marked in FIG. 1 after various steps of fabrication.

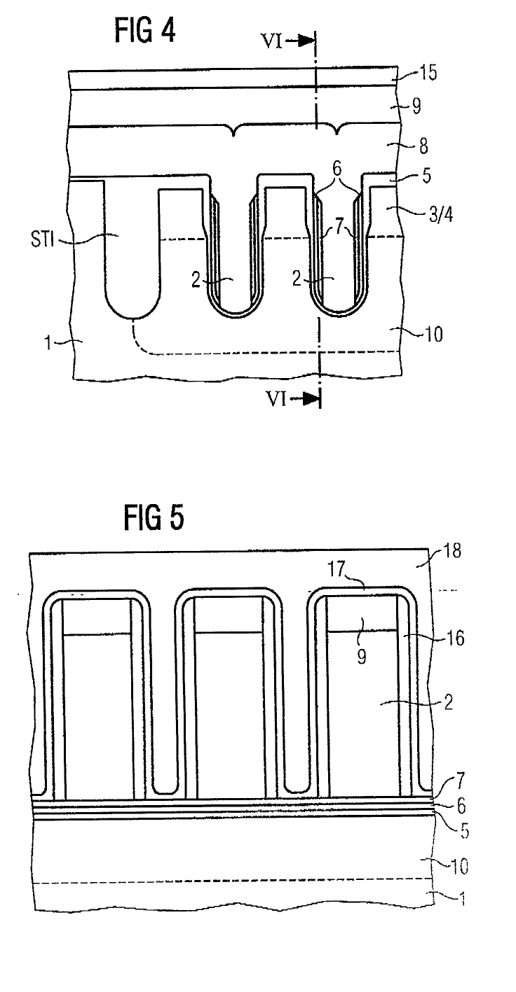

FIG. 4 shows an alternative configuration, in the cross section corresponding to that shown in FIG. 3.

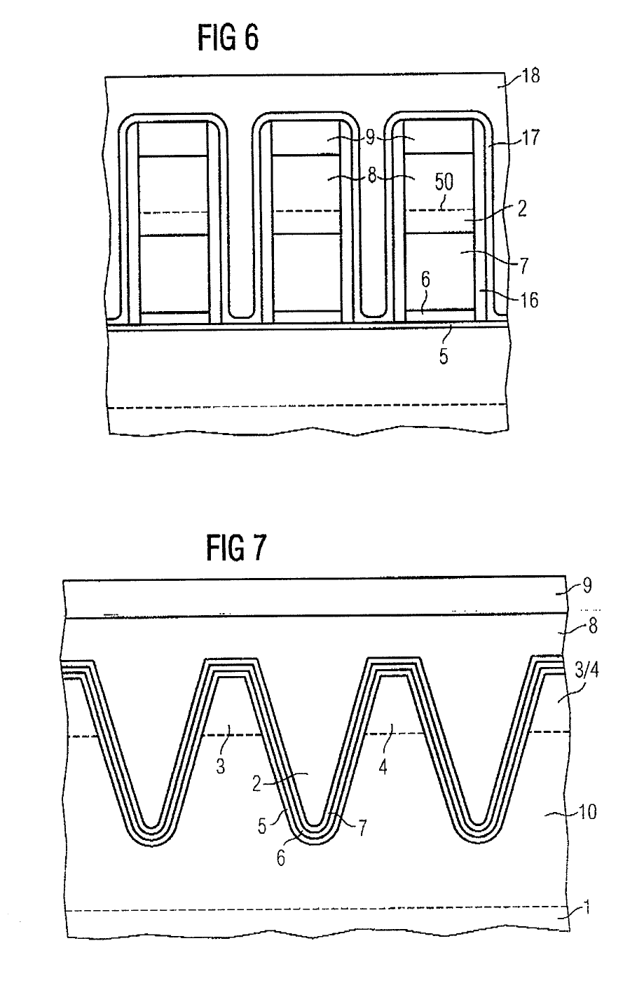

FIGS. 5 and 6 show the embodiments shown in FIGS. 3 and 4 in the cross sections marked in FIGS. 1 and 4.

FIG. 7 shows a further exemplary embodiment in a cross section corresponding to that shown in FIG. 3.

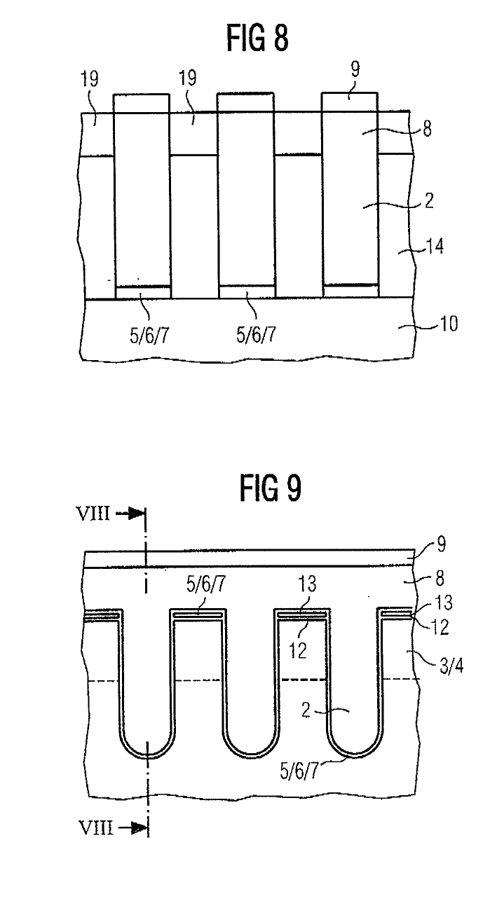

FIGS. 8 and 9 show cross sections corresponding to FIGS. 5 and 3, respectively, for a further embodiment.

FIG. 1 illustrates a typical layout for an arrangement of memory cells, which is provided as a memory, in a diagrammatic plan view. In the region which is taken up by the buried bit lines BL1, BL2, . . . , BLn and the word lines WL1, WL2, . . . , WLn arranged above them in closer proximity to the surface of the chip containing this memory, there is situated the layer sequence which is provided as a memory and, in the examples described below, in order to simplify the description, is assumed to be an oxide-nitride-oxide layer sequence or ONO layer sequence. This ONO layer sequence may be interrupted between the bit lines and the word lines or may be present over the entire surface. At the periphery of the memory are the drive components, which preferably comprise circuit logic, designed using CMOS technology, for addressing the memory. To select the bit lines which lead to the source regions and the drain regions of the individual memory cells, in this example there are select transistors T. The gate electrodes of the select transistors, for example for binary addressing, are connected in blocks to select gate lines SG1, SG2, . . . , SGn. A memory architecture of this type is known per se.

A cross section through an excerpt of a first intermediate product of a preferred fabrication method for an example of the memory is illustrated in FIG. 2. Fabrication preferably takes place as part of a CMOS process, which is also used to produce the drive electronics. In this context, it is customary for the top side of a semiconductor body or of a semiconductor layer which has been grown on a substrate initially to be covered with a pad oxide 12 and pad nitride 13. Using a suitable mask technique, the trenches which are provided for the memory and an STI isolation (shallow trench isolation), are etched out, preferably at a minimum width (distance between a source region and a drain region of the same memory cell) of at most 180 nm and are filled with a dielectric material, e.g. an oxide. p-wells and n-wells are formed using an CMOS process which is known per se by implantation of dopant in the semiconductor material. A p-well 10 is preferably fabricated in the region of the memory. A triple well with three regions of alternating sign of the electrical conductivity which are embedded in one another is fabricated for those transistors via which the word lines of the memory are to be connected to a negative potential, in order to be able to erase memory cells using the hot holes (HH) method with a negative gate potential. The bit lines containing the source regions 3 and the drain regions 4 of the individual memory transistors are fabricated by further implantation 11, in this example for n-type conduction. The drain region 4 in each case functions as a source region for the transistor which adjoins it in series. The abovementioned programming method using channel-hot-electrons (CHE) allows any memory cell to store one information bit both via the source region and via the drain region, for which purpose, during programming, the roles of source and drain are exchanged in the fundamentally symmetrical structure of the transistors.

The CHE programming and HH erasing require a hard transition between the conductivities of source or drain and the well. Therefore, dopant for electrical conduction of the opposite sign (in this example p⁺-type conduction) is introduced, preferably together with the implantation of the dopants for source and drain (in this example for n⁺-type conduction), in higher concentrations through deeper implantation into the layer section of the well (in this example p⁻-doped) which adjoins the source or drain.

The trenches 14 which are provided for the gate electrodes of the memory transistors are etched clear, pad nitride and pad oxide are removed and the ONO layer sequence is applied to the entire surface. The ONO layer sequence is preferably a lower boundary layer 5 comprising an oxide which is approximately 2.5 to 8 nm thick (bottom oxide, preferably thermally produced), a memory layer 6 comprising a nitride which is approximately 1 to 5 nm thick (preferably deposited by means of LPCVD [low-pressure chemical vapor deposition]), and an upper boundary layer 7 comprising an oxide which is approximately 3 to 12 nm thick (top oxide, deposited). The trenches are filled with electrically conductive material, preferably with conductively doped polysilicon which is applied to the entire surface, in order to fabricate the gate electrodes 2 and a layer for the conductor tracks 8 which form the word lines WL. A layer 9 which reduces the feed resistance, for example of tungsten silicide or a metal layer of tungsten, is also fabricated.

FIG. 3, which shows part of the cross section through the memory cell arrangement which is marked in FIG. 1, also illustrates a mask layer 15, for example a hard mask of nitride, which has been patterned in strip form and which is used to pattern the gate electrodes and word lines, as a result of the polysilicon which is not covered by the mask being removed, for example by means of RIE (reactive ion etching).

FIG. 4 illustrates an alternative configuration, in which, before the polysilicon layer is applied, the ONO layer sequence has been anisotropically etched away down to the lower boundary layer. Therefore, residues of the ONO layer sequence remain only in those regions on the walls of the trenches which are intended to store captured charge carriers. Otherwise, this exemplary embodiment is identical to the exemplary embodiment shown in FIG. 3.

FIG. 5 illustrates part of a cross section through the memory cell arrangement which runs transversely to the word lines. The embodiment corresponds to the design shown in FIG. 3, with an ONO layer sequence which is present over the entire surface. After the word lines have been patterned in strip form, during which process the ONO layer sequence between the word lines can be at least partially, for example apart from the lower boundary layer 5, or even completely removed down to the semiconductor material, spacers 16 are fabricated, an operation which forms part of the fabrication process of the CMOS drive periphery. If the ONO layer sequence which is illustrated by solid lines in FIG. 5 has been removed between the word lines, the spacers accordingly extend as far as the boundary layer or the semiconductor material. A nitride layer 17 on the entire surface is covered by a planarizing layer 18, with which the remaining parts of the trenches between the word lines are filled. Before the planarization layer 18 is applied, it is also possible for p⁺implantation to take place between the word lines, enabling the insulation between the individual memory cells to be improved.

FIG. 6 shows a section in the same direction as in FIG. 5 through the embodiment illustrated in FIG. 4. In the direction of view given in FIG. 4, the upper interface of the lower boundary layer 5 across the source/drain region 3/4 is indicated with a dashed line 50, as a hidden contour. Above those sections of the ONO layer sequence which have remained as spacer-like residues, there is a section of the gate electrode 2. The lower boundary layer 5 is present over the entire surface. The memory layer 6 and the upper boundary layer 7 are only present on the side walls of the trenches between the gate electrode and the source/drain regions. The boundary between the drawn-in sectional surfaces of these layers is dependent on the precise position of the cross section and on the inclination of the trench walls and the uniformity of the thickness of the layers. The illustration in FIG. 6 is only intended to explain the basic structure, which otherwise corresponds to the structure shown in FIG. 5.

FIG. 7 illustrates a further exemplary embodiment, in which the trenches are of V-shaped design. The details which correspond to the design shown in FIG. 3 are provided with the same reference numerals in this figure. A further advantageous configuration provides for a V-shaped inclination of the trench walls to be present only in the lower region of the trenches, while the trench walls which are lateral with respect to the source and drain regions run substantially in steeply vertical form. As a result it is possible, by means of anisotropic vertical etching of the ONO layer sequence, to remove everything apart from sections which remain in the upper region of the trench walls, i.e. just between the gate electrodes which are to be fabricated and the source/drain regions. Improved insulation of the gate electrode from the semiconductor material in the lower region of the trenches can be achieved if, in that area, after the removal of the memory layer, the lower boundary layer (bottom oxide) is oxidized to a greater thickness.

FIGS. 8 and 9 show a further embodiment in a cross section which runs transversely with respect to the word lines and a cross section which runs parallel to the word lines. In this design, the dielectric material of the trenches 14 which are provided for the gate electrodes is only removed in the regions which are provided for the word lines. The polysilicon which is provided for the word lines is only introduced into the exposed sections of the trenches. It is therefore possible to dispense with the need to refill the trenches which are open between the word lines. To obtain a planar surface, before the trenches 14 filled with dielectric material (preferably oxide) are opened up, a layer 19 of dielectric material (preferably likewise oxide) is applied to the entire area of the surface. A mask in strip form, which covers the surface of the layer 19 which is present between the regions provided for the word lines, makes it possible to etch out the strip-like openings for the word lines, specifically deeply in the trenches, but only to a shallow depth in the layer 19 between the trenches. The layers of the ONO layer sequence 5/6/7 are deposited in these openings.

One advantage of this variant consists in the fact that, after the polysilicon for the gate electrodes 2 and the conductor tracks 8 provided for the word lines has been deposited, the trenches are completely filled. It is therefore possible for the layer 9 which reduces the supply resistance to be fabricated as part of a siliciding process (salicide) used for the components of the drive circuit, from cobalt silicide or titanium silicide, as a result of this layer 9 initially being applied in the form of cobalt, which is then silicided.

It can also be seen from FIG. 9, that the pad nitride 13 which was initially applied has been left in place between the trenches provided for the gate electrodes, above the bit lines (in the section illustrated in FIG. 9, in each case one source region and one drain region of the bit lines can be seen). This is because the pad nitride, if it is not removed prior to the etching of the trenches, can also be used as a mask (etching stop) for etching out of the trenches. During the fabrication of the exemplary embodiment illustrated in FIGS. 8 and 9, this has the particular advantage that, when using masks in strip form to open up the regions provided for the word lines and gate electrodes, those sections of the pad nitride 13 which are still present between the trenches form an expedient etching stop layer, so that deep etching takes place between the bit lines, but the source/drain regions remain in place.

In a further variant of the fabrication method, first of all only those trenches which are provided as STI trenches for insulation from the drive periphery which forms a ring around the memory cell arrangement are etched and filled with dielectric material. The trenches for the gate electrodes are only etched into the semiconductor material during the fabrication of the doped regions for the bit lines and source and drain. However, the design described above has the advantage that the trenches are self-aligned with respect to the outer STI.

Following the patterning of the word lines, the customary process steps which are known per se in order to complete the drive components are carried out. These include in particular the implantations for the source and drain regions of the drive transistors, including the LDD and pocket implants, which take place independently of the memory cell structure. Interconnection is effected via a suitable number of patterned metallization levels which are arranged in intermetal dielectrics. The description of the fabrication of the memory cell arrangement according to the invention also reveals its structure and in particular the structure of the individual memory cell as separately claimed.

Patent claims

1. A memory cell having a memory transistor, which on a top side of a semiconductor body (1) or of a semiconductor layer, has a gate electrode (2), which is arranged between a source region (3) and a drain region (4), which are formed in the semiconductor material, and which is separated from the semiconductor material by dielectric material, characterized in that at least between the source region (3) and the gate electrode (2) and between the drain region (4) and the gate electrode (2) there is a layer sequence which comprises a memory layer (6) between boundary layers (5, 7).

2. The memory cell as claimed in claim 1, in which the gate electrode (2) is arranged in a trench formed in the semiconductor material.

3. The memory cell as claimed in claim 1 or 2, in which at least one boundary layer (5) which faces the semiconductor material, is a material with a relative dielectric constant of at least 3.9.

4. The memory cell as claimed in claim 1 or 2, in which at least one boundary layer (5) which faces the semiconductor material is a material with a relative dielectric constant of at least 7.8.

5. The memory cell as claimed in claim 1 or 2, in which at least one boundary layer (5) which faces the semiconductor material is a material with a relative dielectric constant of at least 20.

6. The memory cell as claimed in claim 1 or 2, in which a barrier level of at least 2 eV is present between the semiconductor material and the memory layer (6).

7. The memory cell as claimed in claim 1 or 2, in which at least one boundary layer (5, 7) contains an oxide or a silicate.

8. The memory cell as claimed in claim 1 or 2, in which at least one boundary layer (5, 7) contains a nitride or an oxynitride.

9. The memory cell as claimed in claim 1 or 2, in which at least one boundary layer (5, 7) contains Al₂O₃ or Ta₂O₅.

10. The memory cell as claimed in one of claims 1 to 9, in which the memory layer (6) is a material selected from the group consisting of undoped silicon, tantalum oxide, tantalate, hafnium silicate, hafnium oxide, titanium oxide, titanate, zirconium oxide, lanthanum oxide and aluminum oxide.

11. The memory cell as claimed in claim 1 or 2, in which the memory layer (6) is tantalum oxide or tantalate.

12. The memory cell as claimed in claim 1 or 2, in which the memory layer (6) is hafnium silicate or hafnium oxide.

13. The memory cell as claimed in claim 1 or 2, in which the memory layer (6) is titanium oxide or titanate.

14. The memory cell as claimed in claim 1 or 2, in which the memory layer (6) is zirconium oxide, lanthanum oxide or aluminum oxide.

15. An arrangement comprising memory cells as claimed in one of claims 1 to 14,
which is provided as a memory,
in which the gate electrodes (2) are each connected in an electrically conductive manner to a conductor track (8) provided as a word line, and
in which the source region (3) and the drain region (4) of a memory cell are simultaneously provided as the drain region and source region, respectively, of an adjacent memory cell.

16. The arrangement as claimed in claim 15, in which the layer sequence comprising the memory layer (6) is applied to the semiconductor material over the entire surface between the gate electrodes (2) and the semiconductor material and between the conductor tracks (8) and the semiconductor material.

17. The arrangement as claimed in claim 15, in which the memory layer (6) is interrupted between the walls of a trench which is present in the semiconductor material and in which at least one gate electrode (2) is arranged and/or between two adjacent trenches.

18. The arrangement as claimed in one of claims 15 to 17, in which the gate electrodes (2) are arranged in V-shaped trenches or at least trenches which have obliquely oriented walls in the semiconductor material.

19. The arrangement as claimed in one of claims 15 to 18, in which the distance between a source region (3) and a drain region (4) of the same memory cell is at most 180 nm.

20. The arrangement as claimed in claim 18, in which the distance between a source region (3) and a drain region (4) of the same memory cell is at most 150 nm.

21. A method for fabricating the memory cell or the arrangement as claimed in one of claims 1 to 20, in which, in a first step, a trench (14) or a plurality of trenches which run parallel to one another and laterally adjoining doped regions, which are provided as source (3), drain (4) and at least one bit line, are fabricated in a semiconductor body (1) or a semiconductor layer,
in a second step, a storage medium is fabricated in the trenches,
in a third step, an electrically conductive material which is provided for a respective gate electrode (2) is introduced into the trench or trenches and at least one conductor track (8) which is provided as a word line is patterned thereon.

22. The method as claimed in claim 21, in which in the first step a plurality of trenches are etched, these trenches are filled with an oxide, implantation of dopant is carried out so as to form the doped regions, and, using a mask, which covers a section of the trenches provided as STI trenches for electrical insulation, the oxide is removed at least in regions which are intended for a gate electrode.

23. The method as claimed in claim 21 or 22, in which, in the second and third steps, the upper boundary layer and the memory layer are removed at least down to the lower boundary layer, at least between the walls of a trench which is present in the semiconductor material and is provided for at least one gate electrode, and/or between two adjacent trenches.

24. The method as claimed in one of claims 21 to 24, in which, in the first step, the trench or trenches is or are filled with dielectric material,
a layer (19) of dielectric material is applied, and before the second step an opening which is in strip form or a plurality of openings which are in strip form and are oriented parallel to one another is or are fabricated in the dielectric material, transversely with respect to the trench or trenches, and, in the third step, the electrically conductive material is introduced into each such opening.
